(19) United States
(12) Patent Application Publication
(10) Pub. No.: US 2005/0019960 A1
(43) Pub. Date: Jan. 27, 2005

(54) Method and apparatus for forming a ferroelectric layer

(76) Inventors: Moon-Sook Lee, Seoul (KR); Byoung-Jae Bae, Suwon-si (KR)

Correspondence Address: HARNESS, DICKEY & PIERCE, P.L.C., P.O. BOX 8910, RESTON, VA, 20195, US

(21) Appl. No.: 10/889,035

(22) Filed: Jul. 13, 2004

(30) Foreign Application Priority Data
Jul. 25, 2003 (KR) 2003-51434

(51) Int. Cl. H01L 21/00

(52) U.S. Cl. 438/3

(57) ABSTRACT

Methods and apparatus for depositing a layer including providing at least one precursor vapor to a process chamber, providing a gas to the process chamber, separate from the at least one precursor vapor, and forming a compound layer from the at least one precursor vapor and the gas on a wafer in the process chamber. The deposition may be a chemical vapor deposition (CVD) deposition method, a metal organic chemical vapor deposition (MOCVD) deposition method, an atomic layer deposition (ALD) deposition method, or other similar deposition method. The compound layer may be at least one of an oxide, nitride, carbide, or other similar layer.

### PRIORITY STATEMENT

This application claims the benefit under 35 U.S.C. § 119(a) of Korean Patent Application No. 2003-0051434, filed on Jul. 25, 2003, the contents of which are hereby incorporated by reference in their entirety.

### BACKGROUND OF THE INVENTION

1. Field of the Invention

The present invention relates to a method and apparatus for forming a ferroelectric layer, and more particularly, to a method and apparatus for forming a ferroelectric layer for a ferroelectric random access memory (FRAM) using metal organic chemical vapor deposition (MOCVD).

2. Description of the Related Art

FRAMs have several advantages over conventional dynamic random access memory (DRAM), such as lower volatility, higher endurance, faster write/read time, and/or lower operation voltage. Ferroelectric layers and hybrid electrodes of conventional capacitor structures of FRAM devices may be fabricated by a chemical solution deposition (CSD) or physical vapor deposition (PVD).

For FRAM devices to be more competitive with other memories, it is believed that further densification employing a one transistor, one capacitor—capacitor over a bit line (1T1C-COB) cell structure and/or improved reliability would be helpful. To realize these, it is may be useful to develop a metal organic chemical vapor deposition (MOCVD) to grow the ferroelectric layer in a simpler capacitor stack structure.

It is known that increasing the deposition temperature of the ferroelectric layer enhances crystalline properties, leading to improved retention properties. However, higher temperatures may degrade the contact resistance.

FIG. 1 (or FIG. 24) illustrates a cross-sectional view of a representative FRAM usable in conjunction with example embodiments of the present invention. As shown in FIG. 1, the FRAM includes a transistor 114 including a gate dielectric oxide 104, a gate electrode 106, a hard mask 108, a gate spacer 110, a source 112a, and a drain 112b. The FRAM also may include first contact pads 118a and second contact pads 118b. The FRAM further may include a first contact hole 121, a bit line 122, second contact holes 125, contact plugs 126, an interim dielectric layer 204, a local plate line 206, a via hole 214 and a main plate line 216. A bottom electrode 130a, a ferroelectric layer 140a, and a top electrode 150a may form a ferroelectric capacitor (200).

There are several issues to consider with regard to realizing a higher density FRAM. These issue may include buried contact plug oxidation, bottom electrode hillock formation, baking retention, backend degradation, and/or lead zirconate-titanate Pb(Zr, Ti)O₃ (PZT) film properties.

A capacitor located on a buried contact plug may degrade due to oxidation during ferroelectric layer deposition. In general, a high deposition temperature produces high crystalline PZT films resulting in high performance FRAM devices. However, increasing the deposition temperature may cause integration issues, such as oxidizing the buried contact plug materials or bottom electrode hillock formation. A barrier layer between the bottom electrode and plug may improve contact resistance and adhesion and may not oxidize during PZT deposition.

The properties of the ferroelectric layer determine the device properties, such as charge and retention, and the properties may depend on the bottom layers under the ferroelectric layer. For example, CSD PZT may employ Pt to enhance (111) crystalline PZT film on an IrOx/Ir barrier layer. However, this hybrid bottom electrode of Pt/IrO/Ir increase costs and may be difficult to etch. Thus, crystalline PZT formation on an Ir single bottom electrode is an issue for high density devices.

Both thermal budget and crystalline properties should be considered when choosing deposition methods and conditions of the ferroelectric layer. The composition and crystalline properties of the PZT may also affect backend processes for example, ILD (interlayer dielectric), IMD (intermetallic dielectric-SiOx, Metal-Al, a copper process causing degradation of the stress endurance.

Ferroelectric materials exhibit spontaneous polarization when an electrical field is applied due to the atomic displacement of body-centered atoms in the perovskite structure. Therefore, the body-centered B atom shown in FIG. 2 moves in response to an external electric field and generates an internal dipole (referred to as spontaneous polarization B atomic displacement).

The remnant polarization state is maintained even after the electrical field is removed. The polarity of the internal dipole is maintained unless the applied electric field is in the opposite direction. (remnant polarization Pr). FIG. 3 illustrates the bi-stable states and FIG. 4 illustrates ferroelectric hysteresis loop cycles of an example ferroelectric material.

Memory manufacturers generally guarantee a life for their memory products. A standard guarantee for memory devices is several years at 50˜100° C., for example, 10 years at 85° C. It is not practical to test for 10 years, so a simulation test is used. A standard simulation test is an acceleration test which means exposure to a high temperature for a shorter period of time. Failures may be accelerated at a high temperature, so memory manufacturers can measure the activation energy of the failure-reaction from the temperature dependence data such as measuring failures at 50, 75, 100, 125, 150, and 200° C.

Memory manufacturers can predict the retention of the device from this activation energy data in the form “time scale at a temperature”. Before completing all the activation energy data, the retention of similar devices can be compared at one temperature, based on a similar failure mechanism. Typically, 125° C. and 150° C. tests are performed. FIG. 5 illustrates initial and baking hysteresis loops. As shown in FIG. 5, after baking the retention falls below the minimum sensing margin. In FRAM devices, the loss of remnant polarization (2Pr, where 2Pr is >10 mC/cm2) is a typical failure mode.

FIG. 6 is a scanning electron microscope (SEM) image of a conventional ferroelectric capacitor formed by a MOCVD-PZT process at a deposition temperature of 600° C. to improve the ferroelectric layer (111)+(100) mixed orientation. The MOCVD-PZT deposition method used in FIG. 6 premixes the metal organic source and oxygen, has a room temperature of 25° C. for the entering oxygen, and the metal organic source enters at a temperature of 200° C. The conventional ferroelectric capacitor includes an Ir/TiAlN/W plug under the ferroelectric layer. The TiAlN lower barrier layer may inhibit oxygen diffusion and protect the underlying W plug during the PZT deposition process. Accordingly, TiAlN may play a role as a barrier to obtain contact resistance.

FIG. 7a illustrates a conventional ferroelectric capacitor fabrication process. As shown in FIG. 7a, to avoid the buried contact resistance degradation, double Ir layers are employed. The double Ir layer complicates the fabrication process in terms of cost, because Ir is an expensive material and may be difficult to etch. In the process shown in FIG. 7a, it is also necessary to increase the PZT deposition temperature up to 620° C. in order to obtain high quality oriented (111) PZT films. A higher PZT deposition temperature results in more difficult process chamber maintenance.

FIGS. 7b and 7c illustrate the ferroelectric capacitor and a SEM image of the ferroelectric capacitor, respectively in FIG. 7a.

A recessed Ir barrier layer is inserted between a W plug and capacitor bottom electrode to prevent W oxidation during ferroelectric film deposition, reduce capacitor height, etc., i.e., high temperature process. The ferroelectric capacitor may include an IrOₓ top electrode, a 120-nm thick MOCVD PZT layer, and an Ir bottom electrode. A high temperature single mask etching technique was performed to form the ferroelectric capacitor with a steep side wall slope angle of 75° as shown in FIG. 7c. Following the ferroelectric capacitor fabrication, an encapsulation layer and interlayer dielectric films are deposited before a conventional metallization process. Stacked ferroelectric capacitors were fabricated on W plugs as shown in FIGS. 7b-7c.

The recessed Ir barrier enables the area of the top electrode to be kept as wide as possible after high temperature single mask etching. Capacitors with high aspect ratio were formed by high temperature single mask etching at 400° C. after the top electrode IrOₓ deposition.

However, the above method has the following problems. The iridium (Ir) is formed after forming the recessed Ir barrier layer. The formation process of the recessed Ir barrier layer is complicated, requiring an iridium (Ir) deposition process and CMP (chemical mechanical polishing) process. A misalignment may also exist when the recessed Ir barrier layer and the bottom electrode are formed by a photolithography process and when the capacitor area is reduced because of an integration increase of the device. Also, a high temperature (about 620° C.) is needed to deposit the oriented (111) PZT. Accordingly, maintenance is difficult because the process temperature of the organic metal oxide CVD equipment is high.

FIG. 7d illustrates a comparison of crystalline structures and electric properties between the randomly oriented PZT and (111)-oriented PZT. Larger switching charge, better retention and higher imprint resistance are achieved by the (111)-oriented PZT capacitor due to its good crystal quality.

FIG. 8 shows x-ray diffraction patterns of 120 nm MOCVD PZT at 580° C. and 620° C. on an Ir bottom electrode. The (111)-oriented PZT was grown at 620° C. with a seeding layer, whereas the PZT grown at 580° C. was randomly oriented without a seeding layer.

Results of reliability tests are shown in FIG. 9. FIG. 9 illustrates changes in switching charge of the (111)-oriented PZT capacitor (circles) and the randomly oriented PZT capacitor (squares) during 150° C. baking in the retention test. As shown, switching charge (same data read) on the (111)-single orientation preferred PZT capacitor remained stable with time, although switching charge on the randomly oriented PZT capacitor slightly decreased.

Results of other reliability tests are shown in FIG. 10. FIG. 10 illustrates changes in switching charge of the (111)-oriented PZT capacitor (circles) and the randomly oriented PZT capacitor (squares) during 150° C. backing in the retention test. While the randomly oriented PZT capacitor abruptly decreases, the (111)-oriented PZT capacitor shows excellent imprint resistance. As shown, switching charge (opposite data read) on the (111) oriented PZT capacitor is also stable, while randomly oriented PZT decreased to nearly zero. Therefore, the (111)-oriented PZT capacitor is superior to the randomly oriented PZT in both retention and imprint resistance.

FIG. 11-13 illustrate conventional apparatus for performing MOCVD-PZT. The apparatus of FIGS. 11-13 have several issues. First, each focuses on uniform mixing of the metal organic source and oxygen. The apparatus of FIG. 11 uses a premixer, the apparatus of FIG. 12 uses a blocker, and apparatus of FIG. 13 uses a mixing bowl. Second, each may have chemistry issues due to decomposition or stable intermediate state formation, where the vaporized metal source (at ˜200° C.)+O2−>M-O bonded state (at ˜300° C.) and a premixing issue, where the mixing temperature should be below decomposition temperature and a process window for the premixing zone may be limited to 200˜250° C. (in a dual showerhead, temperatures above 300° C. or higher may be applied).

Third, if decomposition occurs in the gap between a showerhead and wafer, the gap space can be decreased by hardware control and the wafer temperature can be decreased.

### SUMMARY OF THE INVENTION

Example embodiments of the present invention are directed to methods of depositing a layer at a relatively low temperature.

Example embodiments of the present invention are directed to methods of depositing a layer including providing at least one precursor vapor to a process chamber, providing a gas to the process chamber, separate from the at least one precursor vapor, and forming a compound layer from the at least one precursor vapor and the gas on a wafer in the process chamber.

In example embodiments of the present invention, the deposition method is a MOCVD deposition method, a chemical vapor deposition (CVD) deposition method, an atomic layer deposition (ALD) deposition method, or other similar deposition method.

In example embodiments of the present invention, the compound layer is at least one of an oxide, nitride, carbide, or other similar layer.

Example embodiments of the present invention are also directed to methods of depositing a metal compound including providing at least one metal precursor vapor to a process chamber, providing a gas to the process chamber, separate from the at least one metal precursor vapor and forming a metal compound layer from the at least one metal precursor vapor and the gas on a wafer in the process chamber.

In example embodiments of the present invention, the temperature of the wafer in the process chamber is relatively low, for example, 580° C. or less. In example embodiments of the present invention, the temperature of the wafer in the process chamber is 520-580° C. or 540-560° C.

In example embodiments of the present invention, the metal compound layer is part of a ferroelectric layer of a ferroelectric random access memory (FRAM).

In example embodiments of the present invention, the FRAM includes a capacitor stack, including a first top electrode, the ferroelectric layer, a bottom electrode, and a barrier layer.

In example embodiments of the present invention, the first top electrode, the ferroelectric layer, the bottom electrode, and the barrier layer are formed with a single mask.

In example embodiments of the present invention, the barrier layer includes a TiAlN barrier layer.

In example embodiments of the present invention, the TiAlN barrier layer improves a crystalline structure of the ferroelectric layer.

In example embodiments of the present invention, the ferroelectric layer is one of a Pb(Ti,Zr)O₃ (PZT), SrBi₂Ta₂O₉ (SBT), or Bi_{3.25}La_{0.75}Ti₃O₁₂ (BLT) ferroelectric layer or a doped PZT, SBT, or BLT ferroelectric layer.

In example embodiments of the present invention, the ferroelectric layer is substantially (111)-oriented PZT.

In example embodiments of the present invention, the ferroelectric layer is substantially (100)-oriented PZT.

### BRIEF DESCRIPTION OF THE DRAWINGS

The present invention will become more fully understood from the detailed description given below and the accompanying drawings, which are given for purposes of illustration only, and thus do not limit the invention.

FIG. 1 illustrates a cross-sectional view of a representative FRAM of example embodiments of the invention.

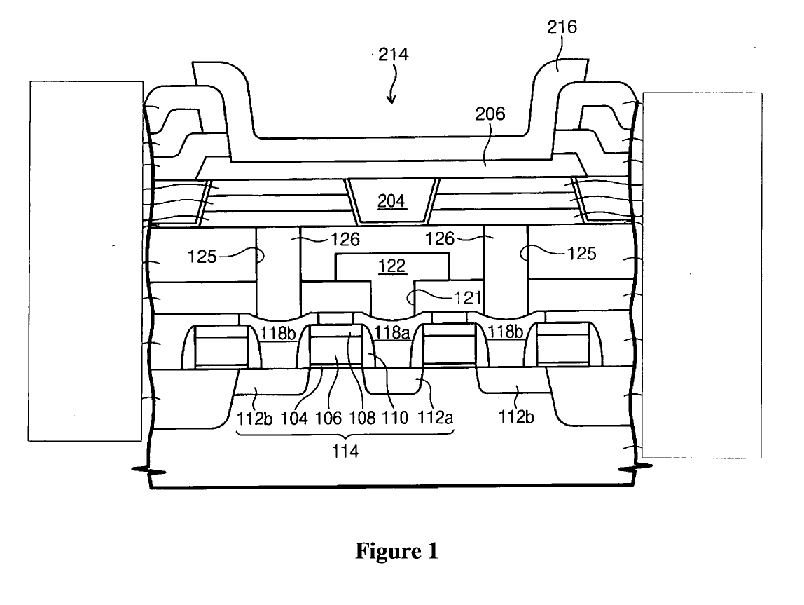

FIG. 2 illustrates a conventional ferroelectric hysteresis loop.

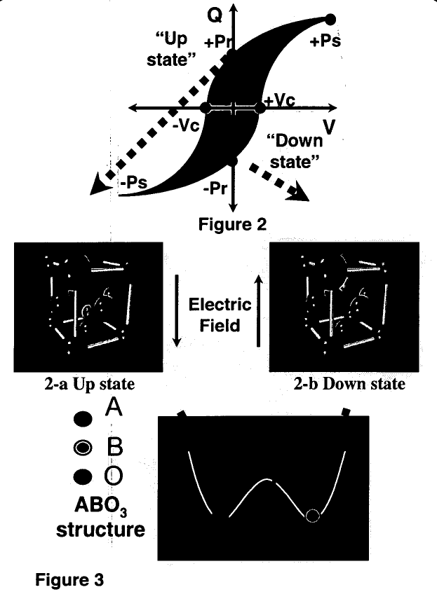

FIG. 3 illustrates the bi-stable states of a conventional ferroelectric material.

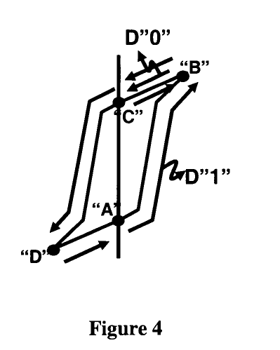

FIG. 4 illustrates ferroelectric hysteresis loop cycles of a conventional ferroelectric material.

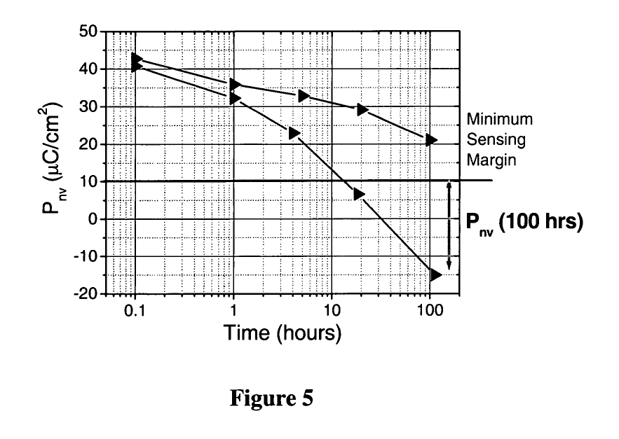

FIG. 5 illustrates initial and baking hysteresis loops for a conventional acceleration test.

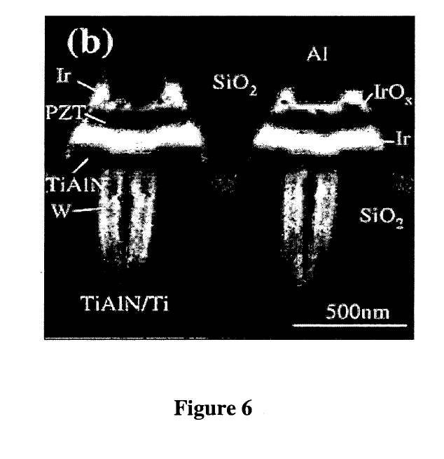

FIG. 6 is a scanning electron microscope (SEM) image of a conventional ferroelectric capacitor formed by a MOCVD-PZT process.

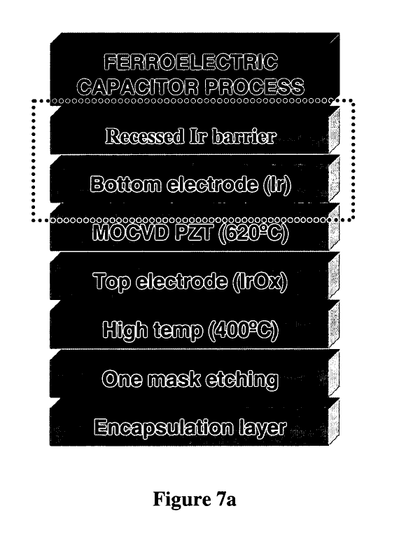

FIG. 7a illustrates a conventional ferroelectric capacitor fabrication process.

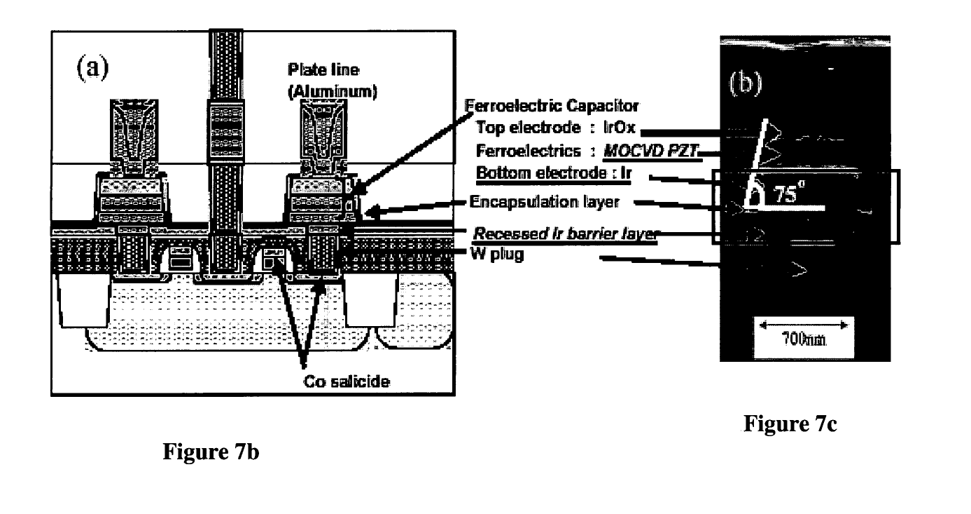

FIGS. 7b and 7c illustrate the ferroelectric capacitor and a SEM image of the ferroelectric capacitor, respectively in FIG. 7a

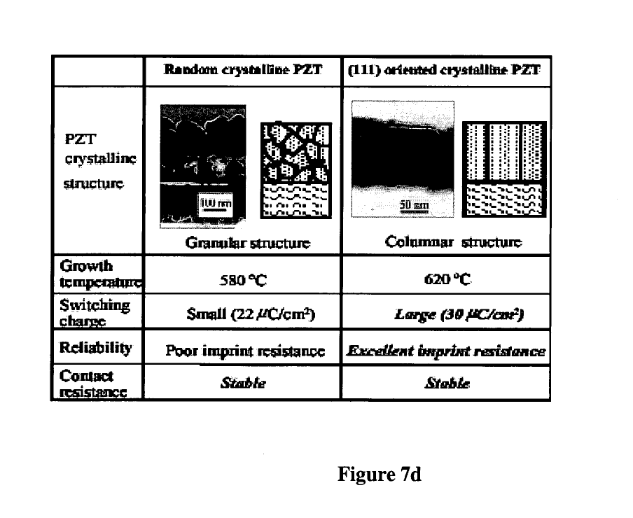

FIG. 7d illustrates a comparison of crystalline structures and electric properties between the randomly oriented PZT and (111)-oriented PZT.

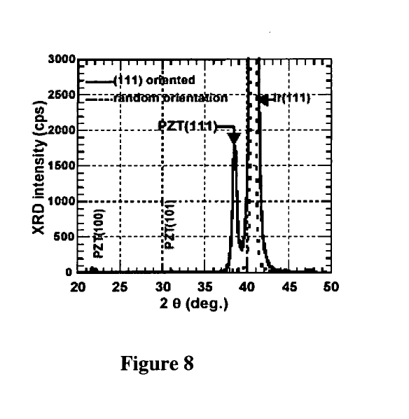

FIG. 8 shows x-ray diffraction patterns of conventional 120 nm MOCVD PZT at 580° C. and 620° C. on an Ir bottom electrode.

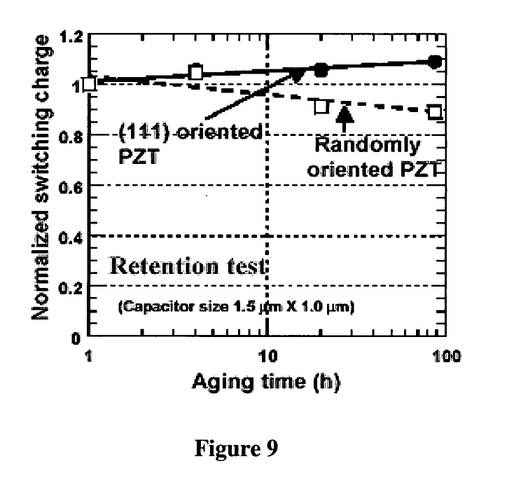

FIGS. 9 and 10 illustrates reliability test results for conventional (111)-oriented PZT randomly oriented PZT capacitors.

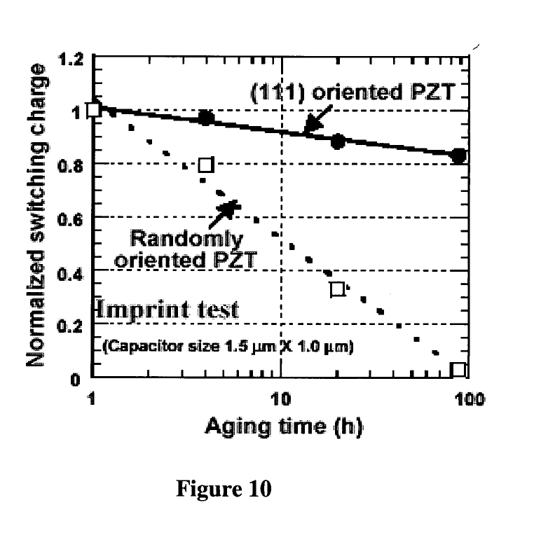

FIG. 11-13 illustrate conventional apparatus for performing MOCVD-PZT.

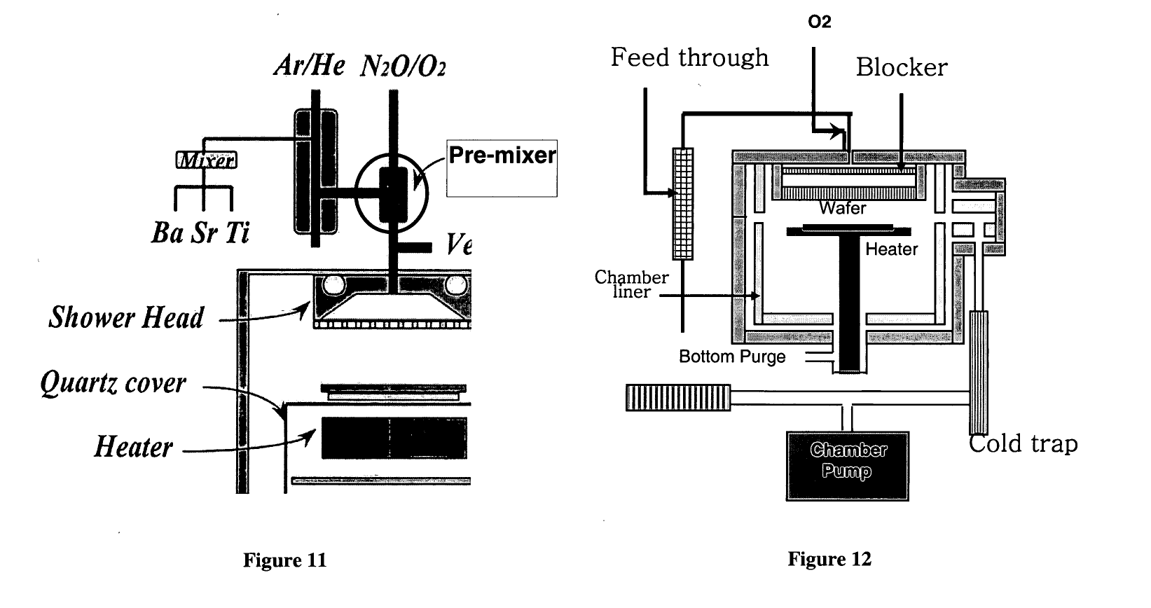

FIG. 14 illustrates an apparatus with an external heater in accordance with an exemplary embodiment of the present invention.

FIG. 15 illustrates an apparatus with an internal heater in accordance with an exemplary embodiment of the present invention.

FIG. 16 illustrates the fabrication of a transistor in accordance with an exemplary embodiment of the present invention.

FIG. 17 illustrates the formation of a bit line in accordance with an exemplary embodiment of the present invention.

FIG. 18 illustrates forming a buried contact (BC) plug in accordance with an exemplary embodiment of the present invention.

FIG. 19 illustrates further processing steps in accordance with an exemplary method of the present invention.

FIG. 20 illustrates further processing steps in accordance with an exemplary embodiment in the present invention.

FIG. 21 illustrates further processing steps in accordance with an exemplary embodiment of the present invention.

FIG. 22 illustrates further processing steps in accordance with an exemplary embodiment of the present invention.

FIG. 23 illustrates further processing steps in accordance with an exemplary embodiment of the present invention in accordance with an exemplary embodiment of the present invention.

FIG. 24 illustrates a vertical and tilt SEM image of MOCVD PZT film grown on an iridium substrate in accordance with an exemplary embodiment of the present invention.

FIG. 25 illustrates a crystalline pattern of a MOCVD PZT film as a function of temperature and hot and cold oxygen in accordance with an exemplary embodiment of the present invention.

FIG. 26a illustrates a crystalline pattern of a MOCVD PZT film as a function of a TiAlN layer and according to temperature and hot and cold oxygen in accordance with an exemplary embodiment of the present invention.

FIG. 26b illustrates a comparison of the characteristics of the three MOCVD PZT films identified in FIG. 27a in accordance with an exemplary embodiment of the present invention.

FIG. 27 illustrates imprint characteristics of a ferroelectric layer formed in accordance with an exemplary embodiment of the present invention.

FIG. 28 illustrates first access charge distribution and cycles of a PZT capacitor formed in accordance with an exemplary embodiment of the present invention over conventional sol-gel PZT capacitors.

FIG. 29 illustrates enhanced retention of PZT capacitors formed according to example embodiments of the present invention over conventional sol-gel PZT capacitors.

FIG. 30 illustrates an improvement of backend process degradation of PZT capacitors formed in accordance with an exemplary embodiment of the present invention over conventional sol-gel PZT capacitors.

FIG. 31 illustrates the contact resistance between a tungsten (W) plug and a bottom electrode in accordance with an exemplary embodiment of the present invention.

It should be noted that these Figures are intended to illustrate the general characteristics of methods and devices of exemplary embodiments of this invention, for the purpose of the description of such exemplary embodiments herein. These drawings are not, however, to scale and may not precisely reflect the characteristics of any given embodiment, and should not be interpreted as defining or limiting the range of values or properties of exemplary embodiments within the scope of this invention.

In particular, the relative thicknesses and positioning of layers or regions may be reduced or exaggerated for clarity. Further, a layer is considered as being formed “on” another layer or a substrate when formed either directly on the referenced layer or the substrate or formed on other layers or patterns overlaying the referenced layer.

### DETAILED DESCRIPTION OF EXEMPLARY EMBODIMENTS OF THE PRESENT INVENTION

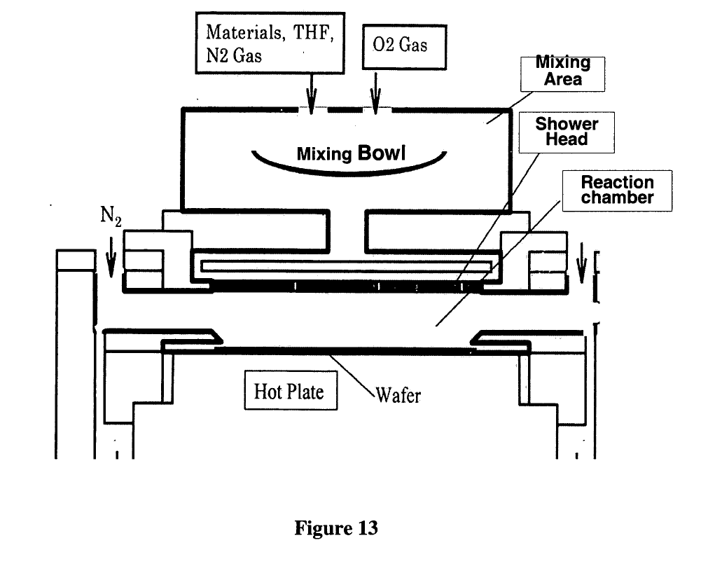

FIG. 14 illustrates an apparatus in accordance with an exemplary embodiment of the present invention. As shown in FIG. 14, the apparatus may include a process chamber 500, a susceptor 510, a showerhead 520, a first gas injection part 540, a second gas injection part 560, and a purge gas injection part 570. The showerhead 520 may further include a first injection part 520a and a second injection part 520b. The first injection part 540 may include a vaporizer 530 which receives a carrier gas and a liquid metal organic source and vaporizes the combination and a valve 542 may supply the mixed vaporized gas to the showerhead 520. The second gas injection part 560 may include an external heater 550 for receiving a gas, such as oxygen gas and a valve 562 for controlling the flow of heated oxygen gas to the second injection part 520b of the showerhead 520. The purge gas injection 570 may include a valve 572 for controlling the flow of purged gas to the first injection part 520a of the showerhead 520.

In example embodiments of the present invention, a distance between the showerhead 520 and the wafer 100 is controllable to improve the uniformity of the resulting layer. In example embodiments of the present invention, the resulting layer is at least one of an oxide, nitride, and carbide layer.

The first injection part 520a may include nozzles 520a′ and the second injection part 520b may include nozzles 520b′. As shown in FIG. 14, the apparatus of FIG. 14 may constitute a metal oxide chemical vapor deposition (MOCVD) apparatus with an external heater 550 attached to an external heating gas line.

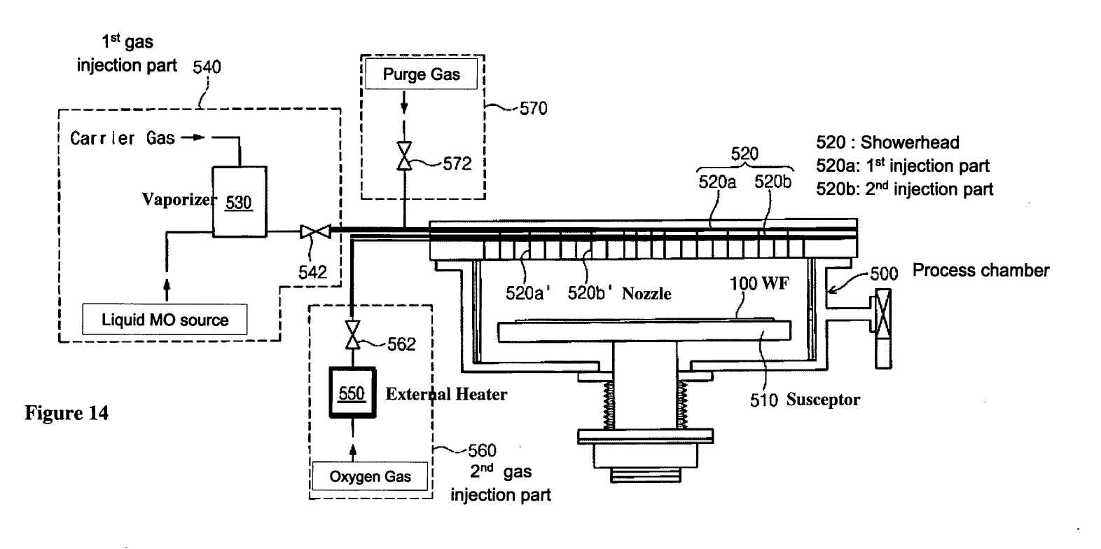

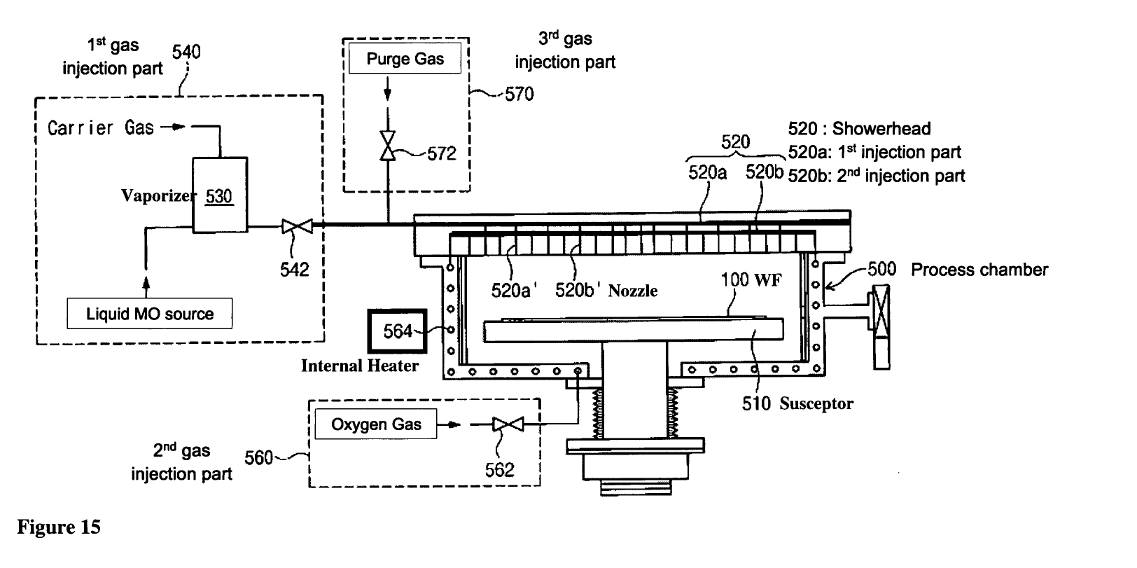

FIG. 15 illustrates another exemplary embodiment of an apparatus of the present invention. In an exemplary embodiment, the apparatus of FIG. 15 may also constitute a MOCVD apparatus. As illustrated, in the environment of FIG. 16, the apparatus includes an internal heater 564.

The apparatus of FIG. 15 may have common elements with the apparatus illustrated in FIG. 15 and discussion of these common elements will be omitted. In the apparatus of FIG. 15, the process chamber 500 includes an internal heater 564, for example, embedded in the wall and floor of the process chamber 500. In an exemplary embodiment illustrated in FIG. 16, the second gas injection part 560 may includes a valve 562 for supplying oxygen gas to the internal heater 564. In example embodiments of the present invention, a distance between the showerhead 520 and the wafer 100 is controllable to improve the uniformity of the resulting layer.

Other apparatuses and variants thereof in accordance with an exemplary embodiments of the present invention, which may be used to perform the various deposition methods in accordance with exemplary embodiments of the present invention may be found in U.S. application Ser. No. 10/784,772 to Moon-Sook Lee and Byoung-Jae Bae entitled “Apparatus for Fabricating Semiconductor Devices filed on Feb. 24, 2003, the entire contents of which are hereby incorporated by reference.

In example embodiments of the present invention, the mixed vaporized gas output from the first injection part 540 includes at least one metal precursor vapor and the second gas output from the second injection part 560 includes oxygen gas. In example embodiments of the present invention, the first gas and the second gas are separately supplied to the process chamber 500. In example embodiments of the present invention, separately providing the at least one metal precursor and the gas reduces or prevents a gas state reaction between the at least one metal precursor and the gas.

In example embodiments of the present invention, no premixing of the at least one metal precursor and the gas occurs due to their introduction to the process chamber 500 due to the first injection part 540 and the second injection part 560.

In example embodiments of the present invention, separately providing the at least one metal precursor and the gas reduces or prevents re-liquefaction and/or heat-decomposition.

In example embodiments of the present invention, the mixed vaporized gas including at least one metal precursor vapor is formed in the vaporizer 530 of the first gas injection part 540. At least one metal source (for example, a liquid metal source) along with a carrier gas and optionally at least one solvent. The at least one metal source and the at least one solvent may be mixed and the mixture vaporized to produce the at least one metal precursor vapor. In example embodiments of the present invention, the carrier gas is an inert gas, such as Ar, N₂, or He.

In example embodiments of the present invention, the gas and the carrier gas are provided in at least a 3:1 ratio.

In example embodiments of the present invention, the gas is heated to a temperature equal to or above a temperature of the at least one metal precursor.

In example embodiments of the present invention, the temperature of the wafer 100 in the process chamber 500 is dependent on a decomposition temperature of the at least one metal precursor. In example embodiments of the present invention, the temperature of a wall of the process chamber 500 is above a vaporization temperature of the at least one metal precursor. In example embodiments of the present invention, a temperature of the first gas (for example, the at least one metal precursor vapor) and a temperature of the second gas (for example, oxygen) is 300° C. or less.

In example embodiments of the present invention, the temperature of the wafer 100 in the process chamber 500 is 580° C. or less, for example, 540-560° C.

In example embodiments of the present invention, a temperature of a susceptor 510 of the process chamber 500 is at 600° C. and an outer wall of the process chamber 500 is at a temperature lower than at 600° C.

In example embodiments of the present invention, the pressure in the process chamber 500 may be used to control a deposition rate and deposition quality of the resulting layer. In example embodiments of the present invention, a pressure in the process chamber is less than 100 Torr, less than 4 Torr, 3 Torr or less, 2.5 Torr or less, or 2 Torr or less.

FIGS. 16-23 illustrate an exemplary method of manufacturing an FRAM 10, in accordance with an exemplary embodiment of the present invention. Exemplary methods of the present invention may be carried out using the exemplary apparatus of FIGS. 14, 15, any of the apparatus disclosed in U.S. application Ser. No. 10/784,772, or any variations and/or combinations thereof.

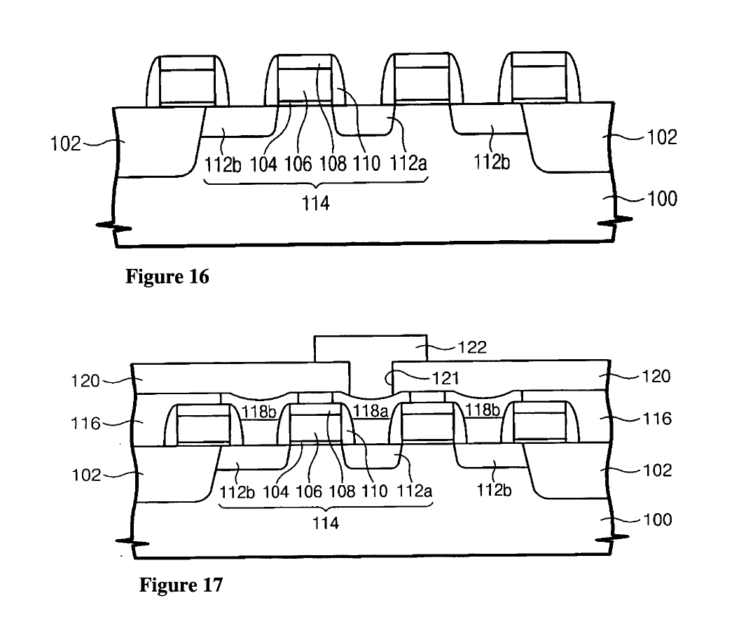

FIG. 16 illustrates the fabrication of an example transistor 114. In an exemplary embodiment, the transistor 114 may be fabricated in a manner similar to the manner in which conventional RAM memory devices are fabricated. As illustrated in FIG. 16, the method may include forming a gate dielectric oxide 104, a gate electrode 106, a hard mask 108, a gate spacer 110, a source 112a, and a drain 112b. Also shown in FIG. 17 are a silicon substrate 100 and an isolation layer 102.

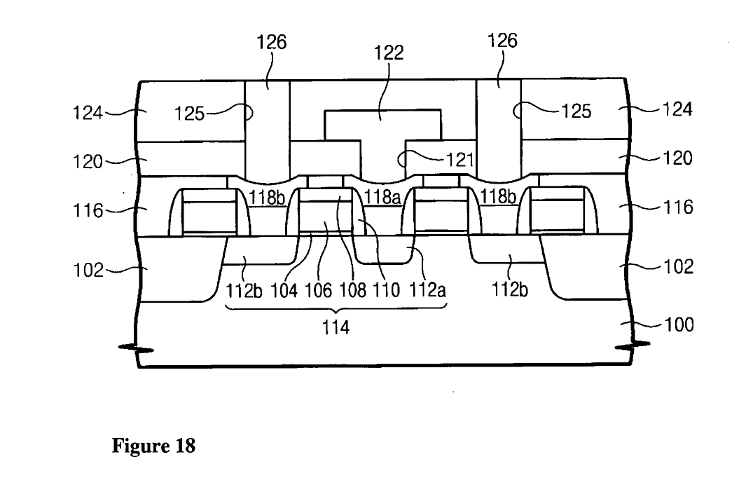

FIG. 17 illustrates the formation of a bit line 122 in accordance with an exemplary embodiment of the present invention. In an exemplary embodiment, the bit line 122 may be formed in a manner similar to the manner used in conventional RAM memory devices. As shown in FIG. 18, the method may further include forming a first inter-dielectric layer 116, a first contact pad 118a, a second contact pad 118b, a second inter-dielectric layer 120, and a first contact hole 121.

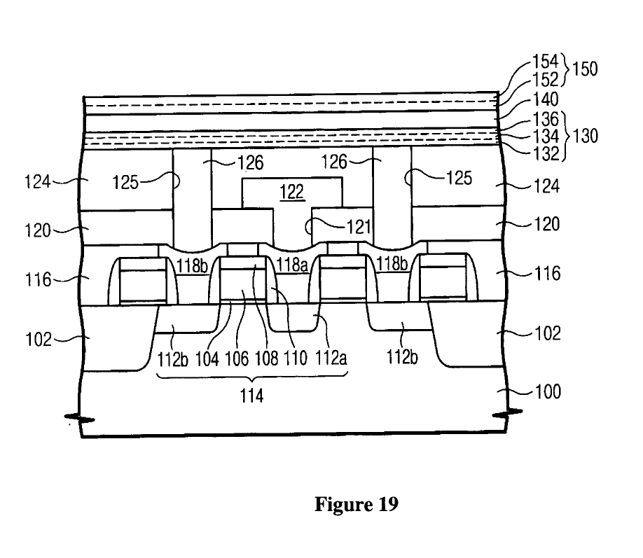

FIG. 18 illustrates forming a buried contact (BC) plug in accordance with an exemplary embodiment of the present invention. In an exemplary embodiment, the BC Plug is formed in a manner similar to the manner for conventional RAM memory devices. As illustrated in FIG. 19, the method may further include forming a third inter-dielectric layer 124, a second contact hole 125, and the BC contact plug 126. In an exemplary embodiment, the BC plug 126 may be formed of poly-silicon or tungsten.

FIG. 19 illustrates further processing steps in accordance with an exemplary method of the present invention. As illustrated in FIG. 19, the method may further include forming a bottom electrode 130, a ferroelectric layer 140, and a top electrode 150. In an example embodiment, the bottom electrode 130 may include a titanium layer 132, a barrier layer 134, and an iridium layer 136. In an example embodiment, the top electrode 150 may include an iridium metal oxide layer 152 and an iridium layer 154. In an example embodiment, the titanium layer 132 may have a thickness of 5-10 nm and the barrier layer 134 may be a TiAlN layer having a thickness of 1-30 nm and may enhance the orientation of the ferroelectric layer 140. In other examples, the barrier layer 134 may include a TiAlN/Ti, TiN, and/or a Ti layer. In other examples, the barrier layer 134 may enhance the orientation of the ferroelectric dielectric layer 140.

In an example embodiment, the iridium layer 136 may have a thickness of 50-150 nm. The thickness of the iridium layer 136 may be selected to prevent or reduce oxidation of the barrier layer 134 and/or to improve the crystalline properties of ferroelectric dielectric layer 140.

In example embodiments of the present invention, the barrier layer 134 includes a Ti barrier layer and a TiAlN barrier layer. In example embodiments of the present invention, the TiAlN barrier layer improves a crystalline structure of the ferroelectric layer 140. In example embodiments of the present invention, the TiAlN barrier layer improves a protection capability of the buried contact plug 126.

In an exemplary embodiment, the ferroelectric layer 140 may be an MOCVD PZT layer. In an example embodiment, the crystalline properties of the PZT are enhanced by the barrier layer 134. The crystalline properties of the PZT may also be enhanced by the crystalline properties of Ir and/or by diffusion of Ti between a TiAlN barrier layer 134 and the PZT ferroelectric dielectric layer 140.

In example embodiments of the present invention, the ferroelectric layer 140 is one of a PZT, SBT, or BLT ferroelectric layer or a doped PZT, SBT, or BLT ferroelectric layer. In example embodiments of the present invention, the ferroelectric layer is substantially (111) or (100) single orientation preferred PZT layer.

In an example embodiment of the present invention, the iridium metal oxide layer 152 may be of a formula IrOx. In an example embodiment, iridium metal oxide layer 152 provides oxygen to ferroelectric dielectric layer 140 which may improve the fatigue characteristics of the resulting memory device. However, iridium oxide has a relatively weak mechanical strength (IrOₓ may be brittle). Accordingly, a iridium layer, in the form of the iridium layer 154, may be deposited on the iridium oxide (IrOₓ) to improve the mechanical strength.

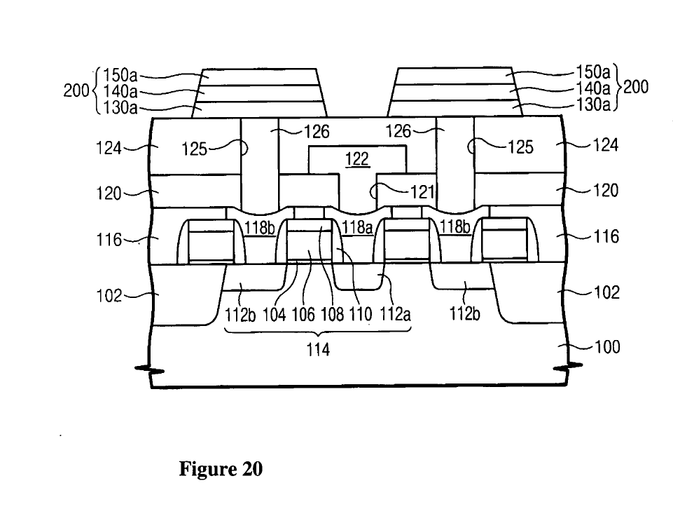

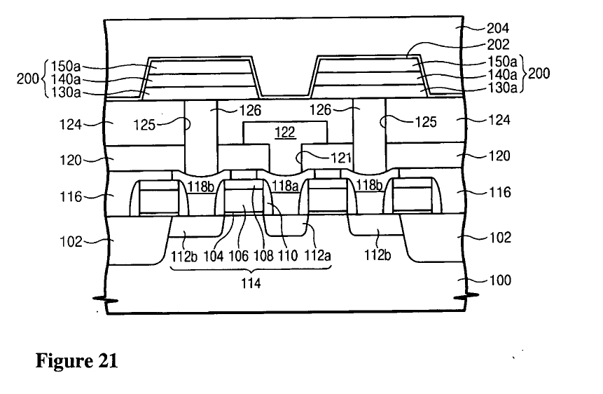

FIG. 20 illustrates further processing steps in accordance with an exemplary embodiment in the present invention. FIG. 21 illustrates a capacitor stack 200 including a bottom electrode 130a, a ferroelectric layer 140a, and a top electrode layer 150a, each of which may be patterned and etched using a single mask or multiple masks.

FIG. 21 illustrates further processing steps in accordance with an exemplary embodiment of the present invention. In FIG. 21, an encapsulating barrier layer (EBL) and/or a hydrogen barrier layer (HBL) 202 may be deposited on the patterned capacitor stack 200. Hydrogen diffusion may cause deterioration of the ferroelectric layer 140a. As a result, the EBL and/or HBL 202 may reduce or prevent hydrogen from diffusing to the ferroelectric layer 140a. In example embodiments, an HBL 202 may include Al₂O₃, TiO₂, Si₃N₄, or a mixture thereof. FIG. 21 also forming a fourth interdielectric layer 204.

In example embodiments of the present invention, the EBL and/or HBL 202 reduces hydrogen diffusion into the ferroelectric layer 140.

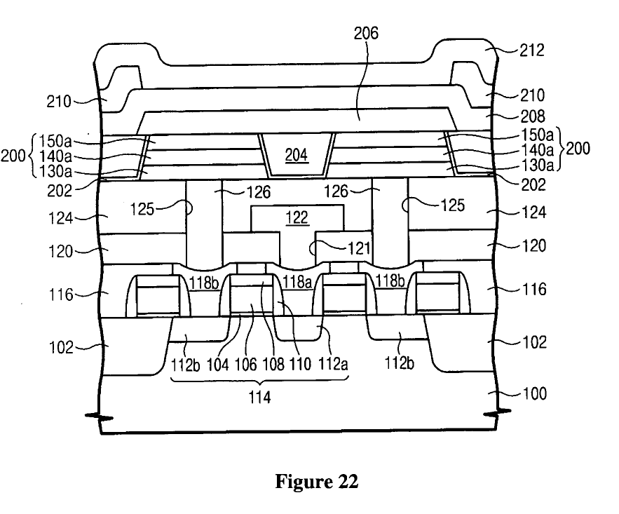

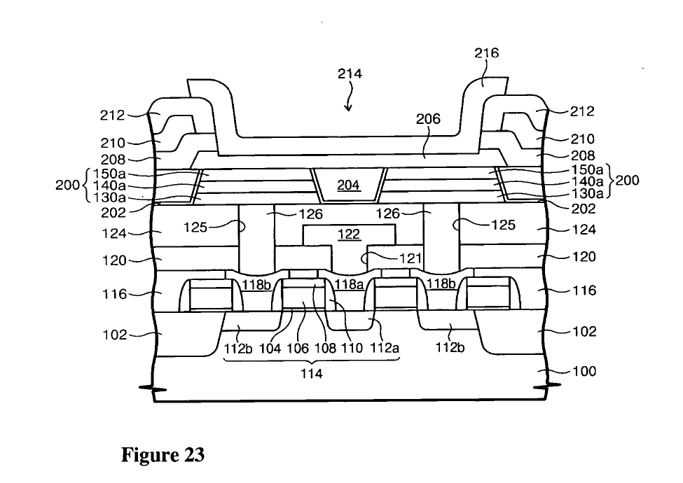

FIG. 22 illustrates additional processing steps in accordance with an exemplary embodiment of the present invention. As illustrated in FIG. 23, the fourth interdielectric layer 204 may be removed to form an isolation oxide layer 204′ on which a local plate line 206, a fifth interdielectric layer 208, a first metal wiring line 210, and/or a sixth interdielectric layer 212 may be formed. In an example embodiment, the first metal wiring line 210 may be made of aluminum.

The fourth interdielectric layer 204 and the EBL/HBL 202 shown in FIG. 22 may be etched by a conventional chemical mechanical polishing and/or conventional etch back process. The isolation oxide layer 204′ between ferroelectric capacitors stacks 200 may be formed on the EBL/HBL 202 and the top electrode 150a may be exposed. The EBL/HBL 202 may cover the side walls of the ferroelectric capacitors 200 or the ferroelectric layer 140a and may reduce or prevent hydrogen diffusion into the ferroelectric layer 140a. The characteristics of the ferroelectric capacitor 200, such as remnant polarization and/or leakage current may be deteriorated if hydrogen atoms penetrate into the ferroelectric layer 140a.

The local plate line 206 may include a metal layer, metal oxide layer with conductivity, metal nitride with conductivity, and/or a compound layer such as TiAlN, Ti, TiN, Ir, IrOₓ, Pt, Ru, RuO₂, Al and/or combinations thereof. The local plate line 206 may be in direct contacted with two adjacent top electrodes 150a. After being deposited, the first metal wiring line 210 may be patterned and the sixth interdielectric layer 212, made of, for example, silicon oxide, may then be deposited by, for example, a CVD process.

FIG. 23 illustrates further processing steps in accordance with an exemplary embodiment of the present invention. As shown, the fifth 208 and sixth 212 interdielectric layers may be selectively etched. The local plate line 206 may be exposed and a via hole 214 may be formed. The local plate line may be over etched when the via hole 214 is formed. A main plate line 216, made of, for example, Al, may be formed and electrically connected with the local plate line 206 through the via hole 214.

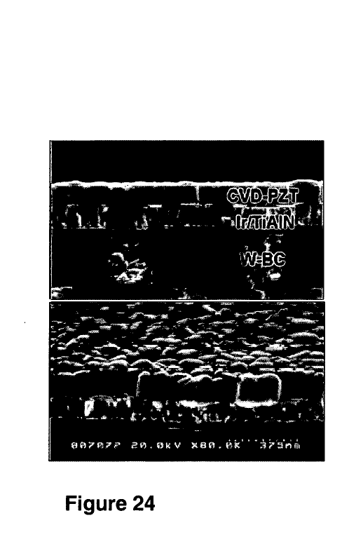

FIGS. 24-31 illustrate example results obtained from example methods of the present invention. FIG. 24 illustrates a vertical and tilt SEM image of a MOCVD PZT film grown on an Ir substrate. As shown in FIG. 24, a substantially uniform PZT film was grown on an Ir substrate without any abnormal non-ferroelectric phase.

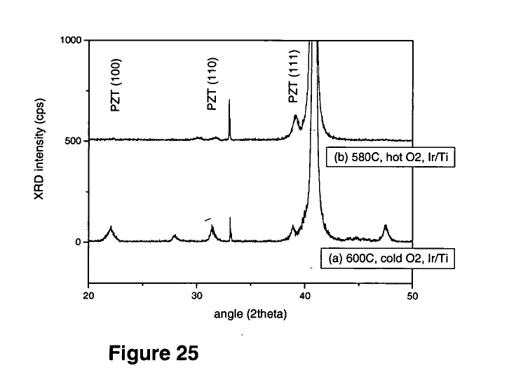

FIG. 25 illustrates a crystalline pattern of a MOCVD PZT film as a function of temperature and hot and cold oxygen. Line (a) illustrates a temperature 600° C. or above with cold O₂. As shown in FIG. 25, the (100), (110), and (111) oriented PZT are substantially the same, which means that a randomly oriented PZT has been grown.

Line (b) illustrates a temperature below 600° C. (for example 580° C., 520-580° C., or 540-560° C.) with hot O₂. As shown in FIG. 25, the (111) oriented PZT is over 90% compared to the (100) and (110) oriented PZT. This means that a crystallization pattern of the (111) or (100) single orientation preferred PZT has been grown.

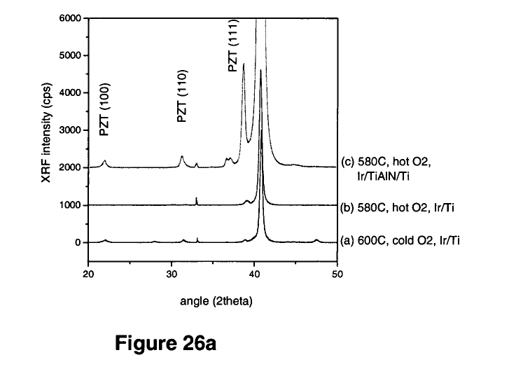

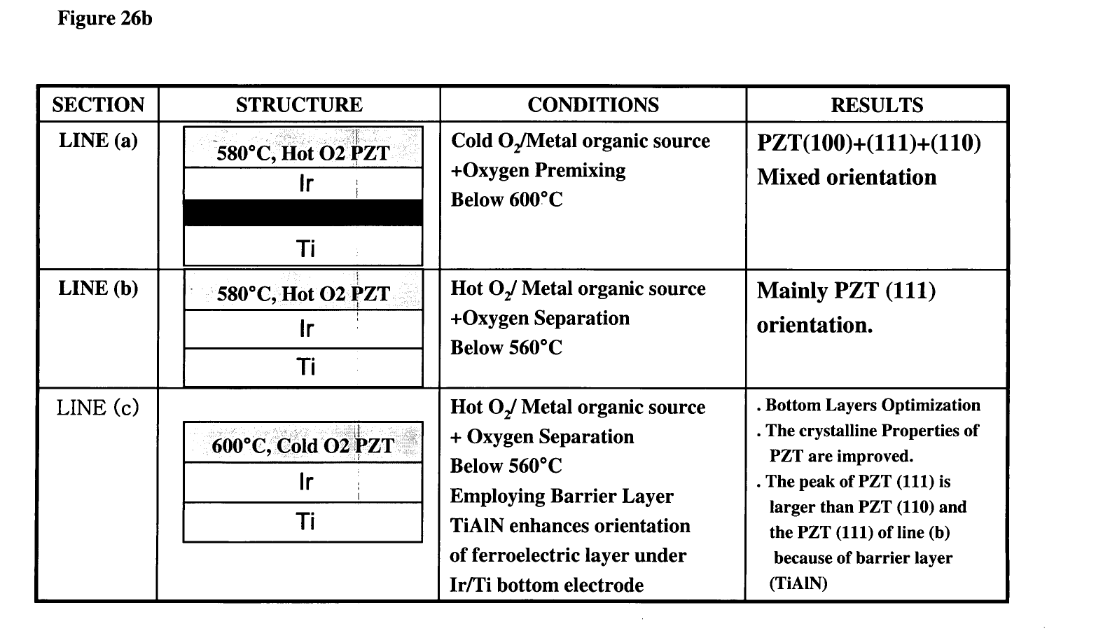

FIG. 26a illustrates a crystalline pattern of a MOCVD PZT film as a function of a TiAlN layer and according to temperature and hot and cold oxygen. Line (a) illustrates a temperature 600° C. or above with cold O₂ and an Ir/Ti barrier layer. Line (b) illustrates a temperature below 600° C. (for example 580° C., 520-580° C., or 540-560° C.) with hot O₂ and an Ir/Ti barrier layer. Line (c) illustrates a temperature below 600° C. (for example 580° C., or even 540-560° C.) with hot O₂ and an Ir/TiAlN/Ti barrier layer. FIG. 26b illustrates a comparison of the characteristics of the three MOCVD PZT films identified by lines (a), (b), and (c) in FIG. 26a.

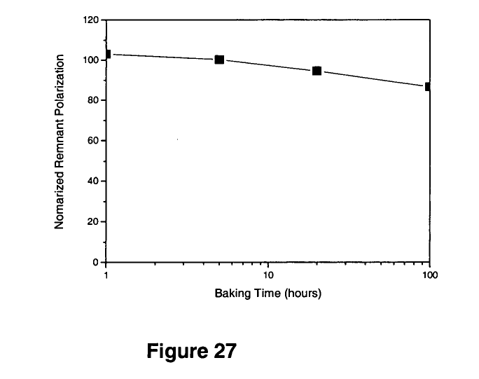

FIG. 27 illustrates imprint characteristic test results of a (111) oriented columnar structure PZT when the process conditions are 580° C. (or 520-580° C., or 540-560° C.) with hot O₂. Imprint characteristics are a measure of reading ability of an opposite stored state after long-term aging. As shown, remnant polarization characteristics remains at about 80% even if baking time passes about 100 hours in FIG. 27. If the remnant polarization characteristics is maintained at about 80%, compared with an initial stage after long-term aging or baking, the reliability of the ferroelectric capacitor is considered excellent. Similar retention properties are obtained from the low temperature grown PZT films.

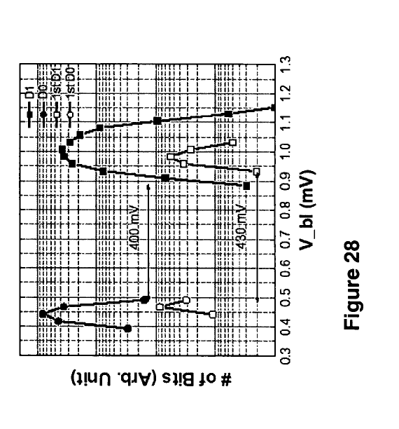

These results are better than those obtained with conventional sol-gel PZT, where the first access charge is significantly lower than the following cycles. FIG. 28 illustrates a comparison of cycles and first access charge distribution of PZT capacitors according to example embodiments of the present invention and conventional sol-gel PZT capacitors. As shown, in the PZT according to example embodiments of the present invention, there is less difference between the first and subsequent accesses. In the PZT capacitors according to example embodiments of the present invention, it was found that the first access cells show almost identical charge distribution with cycled cells which means that the PZT capacitors according to example embodiments of the present invention may improve the initial first access charge window and retention property of a high density FRAM.

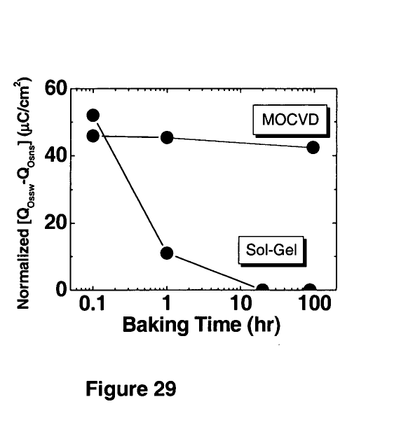

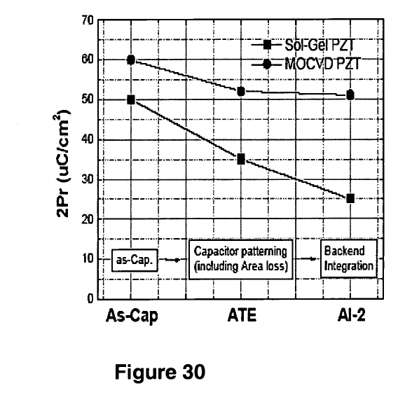

FIG. 29 illustrates enhanced retention and FIG. 30 illustrates an improvement of backend process degradation of PZT capacitors according to example embodiments of the present invention over conventional sol-gel PZT capacitors.

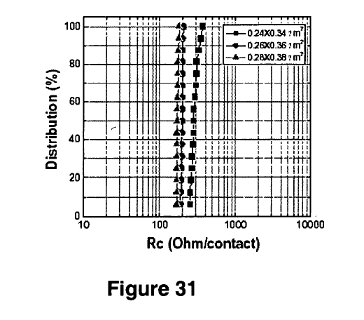

FIG. 31 illustrates the contact resistance between a tungsten (W) plug and a bottom electrode, which was monitored below 200 ohm per contact after full integration. FIG. 32 indicates that even after a relatively long time processing for PZT deposition at around 580° C., an Ir/TiAlN diffusion barrier may still properly block oxygen diffusion, thus resulting in no formation of oxidized layer between the tungsten (W) plug and the bottom electrode. By depositing the PZT layer at lower temperature, it is not necessary to add any extra processing (such as an added recess Ir layer) to obtain a more stable barrier contact plug resistance.

It will be apparent to those skilled in the art that other changes and modifications may be made in the above-described exemplary embodiments without departing from the scope of the invention herein, and it is intended that all matter contained in the above description shall be interpreted in an illustrative and not a limiting sense.

1. A metal compound deposition method, comprising:
providing at least one metal precursor vapor to a process chamber;
providing a gas to the process chamber, separate from the at least one metal precursor vapor; and
forming a metal compound layer from the at least one metal precursor vapor and the gas on a wafer in the process chamber.

2. The method of claim 1, wherein separately providing the at least one metal precursor and the gas reduces or prevents a gas state reaction therebetween.

3. The method of claim 1, wherein no premixing of the at least one metal precursor and the gas occurs.

4. The method of claim 1, wherein the at least one metal precursor and the gas are separately provided using a dual injection part showerhead including one injection part for the at least one metal precursor and one injection part for the gas.

5. The method of claim 4, wherein a distance between the dual injection part showerhead and the wafer is controllable to improve the uniformity of the metal compound layer.

6. The method of claim 1, further comprising heating the gas to a temperature equal to or above a temperature of the at least one metal precursor.

7. The method of claim 1, wherein the temperature of the wafer in the process chamber is dependent on a decomposition temperature of the at least one metal precursor.

8. The method of claim 1, wherein the temperature of a wall of the process chamber is above a vaporization temperature of the at least one metal precursor.

9. The method of claim 1, wherein a temperature of the gas is 300° C. or less.

10. The method of claim 1, wherein the temperature of wafer in the process chamber is 600° C. or less.

11. The method of claim 1, wherein the temperature of the wafer in the process chamber is 580° C. or less.

12. The method of claim 11, wherein the temperature of wafer in the process chamber is 520-580° C.

13. The method of claim 11, wherein the temperature of wafer in the process chamber is 540-560° C.

14. The method of claim 1, wherein the temperature of the at least one metal precursor vapor is 300° C. or less.

15. The method of claim 1, wherein the pressure in the process chamber is used to control a deposition rate and deposition quality of the metal compound layer.

16. The method of claim 1, wherein a pressure in the process chamber is less than 100 Torr.

17. The method of claim 16, wherein the pressure in the process chamber less than 4 Torr.

18. The method of claim 17, wherein the pressure in the process chamber is 3 torr or less.

19. The method of claim 18, wherein the pressure in the process chamber is 2.5 Torr or less.

20. The method of claim 19, wherein the pressure in the process chamber is 2 Torr or less.

21. The method of claim 1, further comprising:
supplying at least one metal source;
supplying at least one solvent;
mixing the at least one metal source and the at least one solvent;
supplying a carrier gas; and
vaporizing the mixture of the at least one metal source and at least one solvent to produce the at least one metal precursor vapor.

22. The method of claim 21, wherein the carrier gas is an inert gas.

23. The method of claim 22, wherein the inert gas is Ar, N₂, or He.

24. The method of claim 1, wherein the metal compound layer is part of a ferroelectric layer of a ferroelectric random access memory (FRAM).

25. The method of claim 24, further comprising:
forming a capacitor stack, including a first top electrode, the ferroelectric layer, a bottom electrode, and a barrier layer of the ferroelectric random access memory (FRAM) with a single mask.

26. The method of claim 25, further comprising:
forming a Ti barrier layer and a TiAlN barrier layer of the ferroelectric random access memory (FRAM).

27. The method of claim 26, wherein the TiAlN barrier layer improves a crystalline structure of the ferroelectric layer.

28. The method of claim 26, wherein the TiAlN barrier layer improves a crystalline structure of the bottom electrode.

29. The method of claim 26, wherein the TIAlN barrier layer improves a protection capability of a buried contact plug.

30. The method of claim 25, further comprising:
forming an encapsulation barrier layer of the ferroelectric random access memory (FRAM).

31. The method of claim 30, wherein the encapsulation barrier layer reduces hydrogen diffusion into the ferroelectric layer.

32. The method of claim 25, further comprising:
forming a second top electrode of the ferroelectric random access memory (FRAM).

33. The method of claim 25, further comprising:
forming a bit line of the ferroelectric random access memory (FRAM).

34. The method of claim 25, further comprising:
forming a barrier contact plug of the ferroelectric random access memory (FRAM).

35. The method of claim 1, wherein the gas is oxygen gas and a temperature of the oxygen gas is 300° C. or less.

36. The method of claim 25, wherein the ferroelectric layer is one of a PZT, SBT, or BLT ferroelectric layer or a doped PZT, SBT, or BLT ferroelectric layer.

37. The method of claim 25, wherein the ferroelectric layer is substantially (111)-oriented PZT.

38. The method of claim 25, wherein the ferroelectric layer is substantially (100)-oriented PZT.

39. The method of claim 21, wherein the carrier gas is argon.

40. The method of claim 21, wherein the gas is oxygen gas and the oxygen gas and the carrier gas are provided in at least a 3:1 ratio.

41. The method of claim 21, wherein the at least one metal source includes metal atoms.

42. The method of claim 1, wherein separately providing the at least one metal precursor and the gas reduces or prevents re-liquefaction and/or heat-decomposition.

43. The method of claim 1, wherein a temperature of a susceptor of the process chamber is at 600° C. and an outer wall of the process chamber is at a temperature lower than at 600° C.

44. The method of claim 1, wherein the metal compound layer is at least one of an oxide, nitride, and carbide layer.

45. A deposition method, comprising:
providing at least one precursor vapor to a process chamber;
providing a gas to the process chamber, separate from the at least one precursor vapor; and
forming a compound layer from the at least one precursor vapor and the gas on a wafer in the process chamber.

46. The method of claim 45, wherein the deposition method is a MOCVD deposition method.

47. The method of claim 45, wherein the deposition method is a CVD deposition method.

48. The method of claim 45, wherein the deposition method is an ALD deposition method.

49. The method of claim 45, wherein the compound layer is at least one of an oxide, nitride, and carbide layer.

50. The method of claim 45, wherein a partial pressure of the gas is more than two times a partial pressure of a carrier gas and a metal precursor.

51. The method of claim 45, wherein a partial pressure of the gas is two times to five times a partial pressure of a carrier gas and a metal precursor.
